(19) United States
(12) Patent Application Publication
(10) Pub. No.: US 2024/0145464 A1
(43) Pub. Date: May 2, 2024

(54) SEMICONDUCTOR DEVICE AND METHOD OF MANUFACTURING SAME

(71) Applicant: Mitsubishi Electric Corporation, Tokyo (JP)

(72) Inventor: Koichi NISHI, Tokyo (JP)

(73) Assignee: Mitsubishi Electric Corporation, Tokyo (JP)

(21) Appl. No.: 18/453,965

(22) Filed: Aug. 22, 2023

(30) Foreign Application Priority Data
Nov. 1, 2022 (JP) 2022-175414

(51) Int. Cl. H01L 27/06; H01L 21/225; H01L 21/265; H01L 21/266; H01L 29/739; H01L 29/861

(52) U.S. Cl. CPC H01L 27/0664; H01L 21/2253; H01L 21/26513; H01L 21/266; H01L 29/7397; H01L 29/8613

(57) ABSTRACT

A transistor and a diode are formed on a common semiconductor substrate, the semiconductor substrate includes a transistor region and a diode region, the diode region includes an n type first semiconductor layer provided on a second main surface side of the semiconductor substrate, an n type second semiconductor layer provided on the first semiconductor layer, a p type third semiconductor layer provided closer to a first main surface side of the semiconductor substrate than the second semiconductor layer, a first main electrode that applies a first potential to the diode, a second main electrode that applies a second potential to the diode, a plurality of diode trench gates that reach the second semiconductor layer from the first main surface of the semiconductor substrate, and a contact region provided in an upper layer portion of the third semiconductor layer, and the contact region is composed of a conductor material.

### BACKGROUND OF THE INVENTION

### Field of the Invention

The present disclosure relates to a semiconductor device, and particularly to a semiconductor device in which a reverse recovery safe operation region is improved without increasing a recovery loss.

### Description of the Background Art

As an example of a reverse conducting insulated gate bipolar transistor (RC-IGBT) in which an insulated gate bipolar transistor (IGBT) and a freewheeling diode are provided on the same semiconductor substrate, conventionally, as disclosed in FIG. 3 of International Publication No. 2020/213254, for example, a configuration has been proposed in which a trench contact is disposed not only in an IGBT region but also in a diode region, and a high-concentration p-type contact layer is formed at the bottom portion of the trench contact.

In International Publication No. 2020/213254, when the area of the trench contact in the diode region is increased, the p-type contact layer also enlarges, and thus the recovery loss increases as compared with the configuration in which the p-type contact layer is not provided in the diode region.

This is because when the impurity concentration of the p-type impurity layer on the surface of the semiconductor substrate is high, the number of holes implanted into the drift layer increases, the peak current (Irr) during the recovery operation increases, or the time (trr) until the recovery current reaches 0 increases.

In order to reduce the recovery loss, it is necessary to reduce the area of the trench contact. However, when the area of the trench contact is reduced, holes are less likely to be discharged during the recovery operation, and an electric field concentrates on the pn junction due to the accumulated holes, which causes a problem that a reverse recovery safe operation area (RRSOA) of the diode is lowered.

### SUMMARY

An object of the present disclosure is to provide a semiconductor device that improves an RRSOA without increasing the recovery loss.

A semiconductor device according to the present disclosure is a semiconductor device in which a transistor and a diode are formed on a common semiconductor substrate, in which the semiconductor substrate includes a transistor region in which the transistor is formed, and a diode region in which the diode is formed, the diode region includes a first conductivity type first semiconductor layer provided on a second main surface side of the semiconductor substrate, a first conductivity type second semiconductor layer provided on the first semiconductor layer, a second conductivity type third semiconductor layer provided closer to a first main surface side of the semiconductor substrate than the second semiconductor layer, a first main electrode that applies a first potential to the diode, a second main electrode that applies a second potential to the diode, a plurality of diode trench gates provided to reach the second semiconductor layer from the first main surface of the semiconductor substrate, and a contact region provided in an upper layer portion of the third semiconductor layer, and the contact region is composed of a conductor material embedded in a recess portion provided in the third semiconductor layer.

According to the semiconductor device of the present disclosure, by providing the contact region made of the conductor material embedded in the recess portion provided in the upper layer portion of the third semiconductor layer, the contact area between the third semiconductor layer and the first main electrode can be increased even when the contact width is minimized, and the RRSOA can be improved without increasing the recovery loss.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment of the present disclosure;

FIG. 2 is a sectional view illustrating a configuration of the semiconductor device according to the first preferred embodiment of the present disclosure;

FIG. 3 is a plan view illustrating a configuration of a semiconductor device according to a second preferred embodiment of the present disclosure;

FIG. 4 is a sectional view illustrating a configuration of the semiconductor device according to the second preferred embodiment of the present disclosure;

FIG. 5 is a sectional view illustrating a configuration of a semiconductor device according to a third preferred embodiment of the present disclosure;

FIG. 6 is a sectional view illustrating a configuration of a semiconductor device according to a fourth preferred embodiment of the present disclosure;

FIG. 7 is a sectional view illustrating a configuration of a semiconductor device according to a fifth preferred embodiment of the present disclosure;

FIG. 8 is a sectional view illustrating a configuration of a semiconductor device according to a sixth preferred embodiment of the present disclosure;

FIG. 9 is an enlarged plan view illustrating a configuration of a semiconductor device according to a seventh preferred embodiment of the present disclosure;

FIG. 10 is an enlarged plan view illustrating a configuration of the semiconductor device according to the second preferred embodiment of the present disclosure;

FIG. 11 is an enlarged plan view illustrating a configuration of a semiconductor device according to an eighth preferred embodiment of the present disclosure;

FIG. 12 is an enlarged plan view illustrating a configuration of a semiconductor device according to a ninth preferred embodiment of the present disclosure; and

FIG. 13 is a flowchart for explaining a method of manufacturing a semiconductor device of a tenth preferred embodiment of the present disclosure.

### DESCRIPTION OF THE PREFERRED EMBODIMENTS

### <Introduction>

In the following description, n-type and p-type represent the conductivity type of the semiconductor, and in the present disclosure, the first conductivity type is described as n-type and the second conductivity type is described as p-type, but the first conductivity type may be p-type and the second conductivity type may be n-type. In addition, the n⁻ type indicates that the impurity concentration is lower than that of the n-type, and the n⁺ type indicates that the impurity concentration is higher than that of the n-type. Similarly, the p⁻ type indicates that the impurity concentration is lower than that of the p-type, and the p⁺ type indicates that the impurity concentration is higher than that of the p-type.

In addition, terms meaning specific positions and directions such as “upper”, “lower”, “side”, “front”, and “back” may be used, but these terms are used for convenience to facilitate understanding of the contents of the preferred embodiment and are not related to directions when actually implemented.

In addition, the drawings are schematically illustrated, and the mutual relationship between the sizes and positions of images illustrated in different drawings is not necessarily accurately described, and can be appropriately changed. In addition, in the following description, similar constituent elements are denoted by the same reference numerals, and names and functions thereof are also similar. Therefore, a detailed description thereof may be omitted.

### <First Preferred Embodiment>

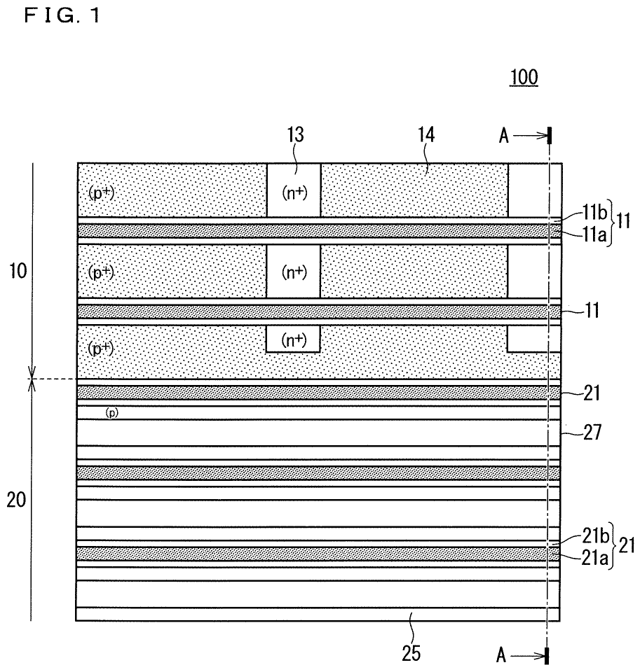

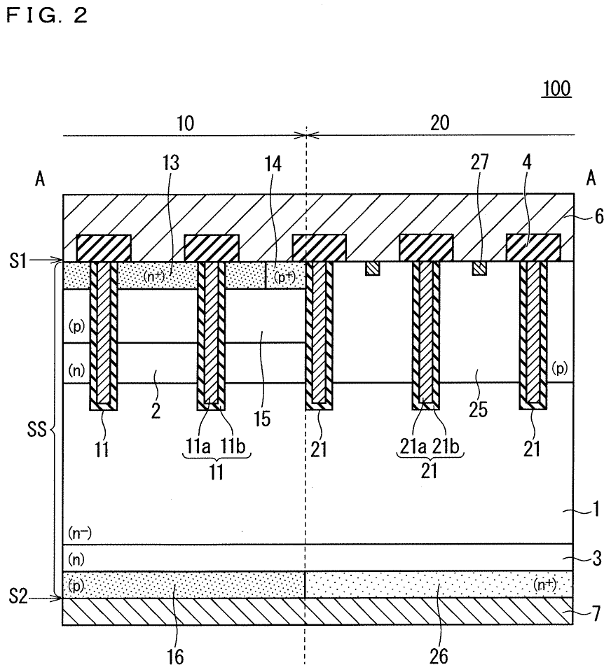

A configuration of an RC-IGBT 100 as a semiconductor device according to a first preferred embodiment of the present disclosure will be described with reference to FIGS. 1 and 2. FIG. 1 is a plan view illustrating a configuration of the RC-IGBT 100, and FIG. 2 is a sectional view taken along line A-A of FIG. 1 as seen in the direction of the arrow. FIG. 1 is a top view of the RC-IGBT 100 when viewed from an emitter electrode 6 (first main electrode) side, but illustration of an emitter electrode 6, an interlayer insulating film 4, and the like is omitted for convenience.

As illustrated in FIG. 1, the RC-IGBT 100 includes an IGBT region 10 and a diode region 20 which are cell regions. In the IGBT region 10, a plurality of active trench gates 11 are arranged, and a p⁺ type IGBT contact layer 14 and an n⁺ type emitter layer 13 are alternately provided between the adjacent active trench gates 11. Although the two active trench gates 11 are illustrated in FIG. 2, the IGBT region 10 in FIG. 2 illustrates only a part of the IGBT region 10 of the RC-IGBT 100, and the number of the active trench gates 11 is not limited to two.

As illustrated in FIG. 1, in the RC-IGBT 100, in the diode region 20, a plurality of diode trench gates 21 are arranged, an anode layer 25 (third semiconductor layer) is provided between the adjacent diode trench gates 21, and a contact region 27 is provided in a stripe shape in a surface of the anode layer 25 to extend parallel to the diode trench gate 21.

As illustrated in FIG. 2, the IGBT region 10 and the diode region 20 of the RC-IGBT 100 are formed in a semiconductor substrate SS. An upper end of the semiconductor substrate SS in the drawing is referred to as a first main surface, and a lower end of the semiconductor substrate SS in the drawing is referred to as a second main surface. The first main surface S1 of the semiconductor substrate SS is a main surface on the front surface side of the RC-IGBT, and the second main surface S2 of the semiconductor substrate SS is a main surface on the back surface side of the RC-IGBT 100.

As illustrated in FIG. 2, the RC-IGBT 100 includes an n⁻ type drift layer 1 (second semiconductor layer) between the first main surface S1 and the second main surface in the IGBT region 10 that is a cell region. The drift layer 1 is a semiconductor layer containing, for example, arsenic (As) or phosphorus (P) as n-type impurities, and an n-type carrier accumulation layer 2 having a higher concentration of n-type impurities than that of the drift layer 1 is provided on the first main surface S1 side of the drift layer 1. The carrier accumulation layer 2 is a semiconductor layer containing, for example, arsenic or phosphorus as n-type impurities.

As illustrated in FIG. 2, a p-type base layer 15 is provided on the first main surface S1 side of the carrier accumulation layer 2. The p-type base layer 15 is a semiconductor layer containing, for example, boron (B), aluminum (Al), or the like as p-type impurities. The base layer 15 is in contact with the gate trench insulating film 11b of the active trench gate 11. On the first main surface S1 side of the base layer 15, an n⁺ type emitter layer 13 is provided in contact with the gate trench insulating film 11b of the active trench gate 11, and a p⁺ type IGBT contact layer 14 is provided in the remaining region. The emitter layer 13 is a semiconductor layer containing, for example, arsenic or phosphorus as an n-type impurity, the IGBT contact layer 14 is a semiconductor layer containing, for example, boron or aluminum as a p-type impurity, and the emitter layer 13 and the IGBT contact layer 14 constitute the first main surface S1 of the semiconductor substrate SS.

As illustrated in FIG. 2, an n-type buffer layer 3 having a higher concentration of n-type impurities than that of the drift layer 1 is provided on the second main surface S2 side of the drift layer 1. The buffer layer 3 is provided to suppress punch-through of a depletion layer extending from the base layer 15 toward the second main surface S2 when the RC-IGBT 100 is in the off state. The buffer layer 3 is formed by, for example, implanting phosphorus or protons (H⁺), and can also be formed by implanting both phosphorus and protons.

As illustrated in FIG. 2, in the IGBT region 10, a p-type collector layer 16 is provided on the second main surface S2 side of the buffer layer 3. That is, the collector layer 16 (fifth semiconductor layer) is provided between the drift layer 1 and the second main surface S2. The collector layer 16 is a semiconductor layer containing, for example, boron or aluminum as a p-type impurity, and the collector layer 16 constitutes the second main surface S2 of the semiconductor substrate SS.

In the IGBT region 10, a trench that penetrates the base layer 15 from the first main surface S1 of the semiconductor substrate SS and reaches the drift layer 1 is formed. A gate trench electrode 11 a is provided in the trench via a gate trench insulating film 11b to constitute the active trench gate 11. The gate trench electrode 11 a faces the drift layer 1 via the gate trench insulating film 11b.

The gate trench insulating film 11b of the active trench gate 11 is in contact with the base layer 15 and the emitter layer 13. When a gate drive voltage is applied to the gate trench electrode 11a, a channel is formed in the p-type base layer 15 in contact with the gate trench insulating film 11b of the active trench gate 11.

As illustrated in FIG. 2, the interlayer insulating film 4 is provided on the gate trench electrode 11a of the active trench gate 11. A barrier metal can also be formed on a region of the first main surface S1 of the semiconductor substrate SS where the interlayer insulating film 4 is not provided and on the interlayer insulating film 4. The barrier metal may be, for example, a conductor containing titanium (Ti), and may be, for example, titanium nitride or TiSi obtained by alloying titanium and silicon (Si).

As illustrated in FIG. 2, the emitter electrode 6 is provided on a region of the first main surface S1 where the interlayer insulating film 4 is not provided and on the interlayer insulating film 4. The emitter electrode 6 may be formed of, for example, an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating.

As illustrated in FIG. 2, the RC-IGBT 100 also has then type drift layer 1 in the diode region 20 as in the IGBT region 10. The drift layer 1 of the diode region 20 and the drift layer 1 of the IGBT region 10 are continuously and integrally formed, and are formed of the same semiconductor substrate SS.

As illustrated in FIG. 2, also in the diode region 20, similarly to the IGBT region 10, the n-type buffer layer 3 is provided on the second main surface S2 side of the drift layer 1. The buffer layer 3 provided in the diode region 20 has the same configuration as the buffer layer 3 provided in the IGBT region 10.

The p-type anode layer 25 is provided on the first main surface S1 side of the drift layer 1. The anode layer 25 is provided between the drift layer 1 and the first main surface S1. In the anode layer 25, the anode layer 25 and the base layer 15 can also be formed at the same time by making the concentration of the p-type impurity the same as that of the base layer 15 of the IGBT region 10. The anode layer 25 constitutes the first main surface S1 of the semiconductor substrate SS.

In the diode region 20, an n⁺ type cathode layer 26 (first semiconductor layer) is provided on the second main surface S2 side of the buffer layer 3. The cathode layer 26 is provided between the drift layer 1 and the second main surface S2. The cathode layer 26 is a semiconductor layer containing, for example, arsenic or phosphorus as n-type impurities, and constitutes the second main surface S2 of the semiconductor substrate SS. In at least a part of the diode region 20, the contact region 27 shallower than the IGBT contact layer 14 of the IGBT region 10 than the first main surface S1 side of the semiconductor substrate SS is formed, and the inside of the contact region 27 is embedded with the same conductor material as the emitter electrode 6.

As illustrated in FIG. 2, a trench that penetrates the anode layer 25 from the first main surface S1 of the semiconductor substrate SS and reaches the drift layer 1 is formed in the diode region 20. A diode trench electrode 21a is provided in the trench of the diode region 20 via a diode trench insulating film 21b to constitute the diode trench gate 21. The diode trench electrode 21a faces the drift layer 1 via the diode trench insulating film 21b.

As illustrated in FIG. 2, an interlayer insulating film 4 is provided on the diode trench electrode 21a of the diode trench gate 21. A barrier metal can also be formed on a region of the first main surface S1 of the semiconductor substrate SS where the interlayer insulating film 4 is not provided and on the interlayer insulating film 4.

As illustrated in FIG. 2, the emitter electrode 6 is provided on a region of the first main surface S1 of the diode region 20 where the interlayer insulating film 4 is not provided and on the interlayer insulating film 4. The emitter electrode 6 is formed continuously with the emitter electrode 6 provided in the IGBT region 10.

As illustrated in FIG. 2, a collector electrode 7 (second main electrode) is provided on the second main surface S2 side of the cathode layer 26. Similarly to the emitter electrode 6, the collector electrode 7 of the diode region 20 is formed continuously with the collector electrode 7 provided in the IGBT region 10. The collector electrode 7 is in ohmic contact with the cathode layer 26, is electrically connected to the cathode layer 26, and also functions as a cathode electrode.

As illustrated in FIG. 2, in the RC-IGBT 100, the contact region 27 shallower than the IGBT contact layer 14 of the IGBT region 10 is formed in at least a part of the diode region 20. With this configuration, the contact area between the anode layer 25 and the emitter electrode 6 in the diode region 20 can be increased, the hole discharge efficiency can be improved, and the RRSOA can be improved.

That is, the IGBT contact layer 14 of the IGBT region 10 is formed at a certain depth or more, for example, 0.5 μm or more in order to lower the resistance of the base layer 15 which is an impurity diffusion layer. When the contact region 27 is formed deeper than the IGBT contact layer 14, the aspect ratio of the contact region 27 increases, and thus embeddability at the time of embedding with the same conductor material as the emitter electrode 6 deteriorates. Therefore, by forming the contact region 27 shallower than the IGBT contact layer 14, embeddability of the emitter electrode can be improved.

In addition, in the configuration in which the contact region 27 is provided, the hole implantation efficiency can be lowered by reducing the impurity concentration of the anode layer 25, and the recovery loss can be reduced. That is, when the contact region 27 is not provided, the hole discharge efficiency decreases and the RRSOA decreases. That is, the control range of the recovery loss is limited in order to prevent a decrease in the RRSOA. However, by providing the contact region 27, the hole discharge efficiency can be improved, the RRSOA can be improved, and the control range of the recovery loss can be expanded. In other words, in the RC-IGBT 100, the recovery loss of the diode region 20 can be determined by the impurity concentration of the anode layer 25, and the recovery loss and the RRSOA can be independently controlled.

In addition, since the contact region 27 is formed in the recess portion from which a part of the anode layer 25 is removed, the contact region 27 is in contact with the anode layer 25 not only on the bottom surface but also on the side surface. Therefore, even when the width of the contact region 27, that is, the contact width is minimized to maintain the aspect ratio to the extent that the embeddability, does not deteriorate, the contact area between the anode layer 25 and the emitter electrode 6 can be increased, and the RRSOA can be improved.

Here, when a barrier metal is formed on the region of the diode region 20 on the first main surface S1 of the semiconductor substrate SS where the interlayer insulating film 4 is not provided and on the interlayer insulating film 4, the conductor material for embedding the contact region 27 may be only the barrier metal, or may be a laminate of the emitter electrode 6 and the barrier metal. Instead of the anode layer 25, the carrier accumulation layer 2 and the base layer 15 may be provided on the first main surface S1 side of the diode region 20 similarly to the IGBT region 10, and the contact region 27 may be provided in the surface of the base layer 15.

### <Second Preferred Embodiment>

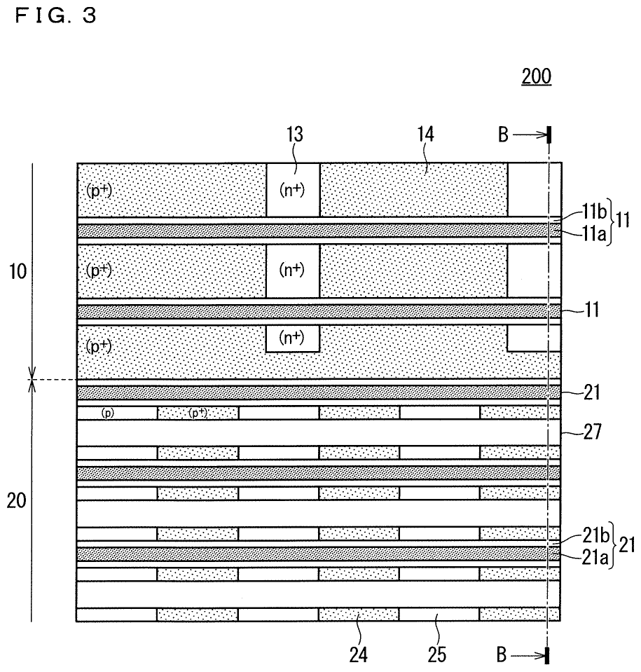

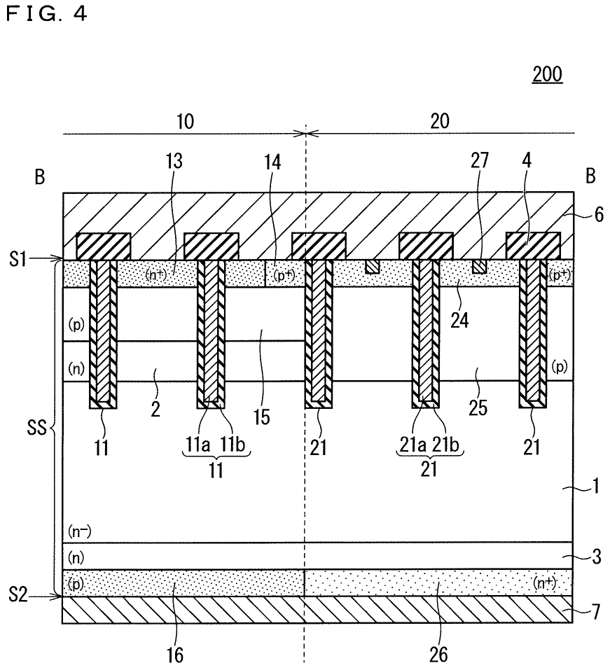

A configuration of an RC-IGBT 200 as a semiconductor device according to a second preferred embodiment of the present disclosure will be described with reference to FIGS. 3 and 4. FIG. 3 is a plan view illustrating a configuration of the RC-IGBT 200, and FIG. 4 is a sectional view taken along line B-B of FIG. 3 as seen in the direction of the arrow. FIG. 3 is a top view of the RC-IGBT 200 when viewed from the emitter electrode 6 side, but illustration of the emitter electrode 6, the interlayer insulating film 4, and the like is omitted for convenience. In FIGS. 3 and 4, the same components as those of the RC-IGBT 100 of the first preferred embodiment described with reference to FIGS. 1 and 2 are denoted by the same reference numerals, and redundant description is omitted.

As illustrated in FIG. 3, in the RC-IGBT 200, a p⁺ type diode contact layer 24 (fourth semiconductor layer) is formed in at least a part of the diode region 20. A plurality of diode contact layers 24 are provided at intervals between the adjacent diode trench gates 21, and a stripe-shaped contact region 27 crosses the center of the plurality of diode contact layers 24. As illustrated in FIG. 4, the diode contact layer 24 is formed to have an impurity concentration of the p-type impurity higher than that of the anode layer 25 and a depth shallower than that of the anode layer 25.

Note that the depth of the diode contact layer 24 is formed deeper than the contact region 27. By adopting such a configuration, as illustrated in FIG. 4, the bottom portion of the contact region 27 comes into contact with the p⁺ type diode contact layer 24, and thus the hole discharge efficiency can be enhanced.

In addition, since the diode contact layer 24 is partially formed in the surface of the anode layer 25 as illustrated in FIG. 3, there is an effect of controlling the recovery loss by adjusting the area of the diode contact layer 24 independently of the contact region 27.

When the diode contact layer 24 is provided, the hole discharge efficiency can be enhanced as compared with a case where no diode contact layer is provided, but on the other hand, the recovery loss increases. However, a recovery loss and a conduction loss defined by a forward voltage drop (VF) are in a trade-off relationship, and in designing the RC-IGBT, it is required to be able to adjust the conduction loss to an optimum conduction loss. By adjusting the impurity concentration of the diode contact layer 24, the conduction loss can be controlled in a wider range than the case of adjusting the impurity concentration of the anode layer 25.

### <Third Preferred Embodiment>

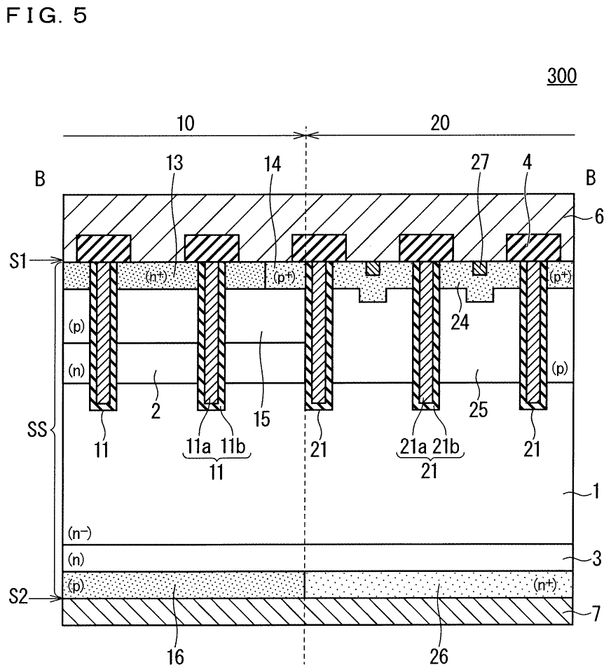

A configuration of an RC-IGBT 300 as a semiconductor device according to a third preferred embodiment of the present disclosure will be described with reference to FIG. 5. FIG. 5 is a sectional view illustrating a configuration of the RC-IGBT 300. The plan view is similar to the RC-IGBT 200 illustrated in FIG. 3, and FIG. 5 is a sectional view corresponding to a sectional view taken along line B-B of FIG. 3 as seen in the direction of the arrow.

In FIG. 5, the same components as those of the RC-IGBT 100 of the first preferred embodiment described with reference to FIG. 2 are denoted by the same reference numerals, and redundant description is omitted.

As illustrated in FIG. 5, in the RC-IGBT 300, the diode contact layer 24 in the diode region 20 is formed such that the depth of the diode contact layer 24 is partially increased in a region below the contact region 27. By adopting such a configuration, the contact area between the diode contact layer 24 and the anode layer 25 can be increased, the hole discharge efficiency can be increased, and the RRSOA can be improved.

### <Fourth Preferred Embodiment>

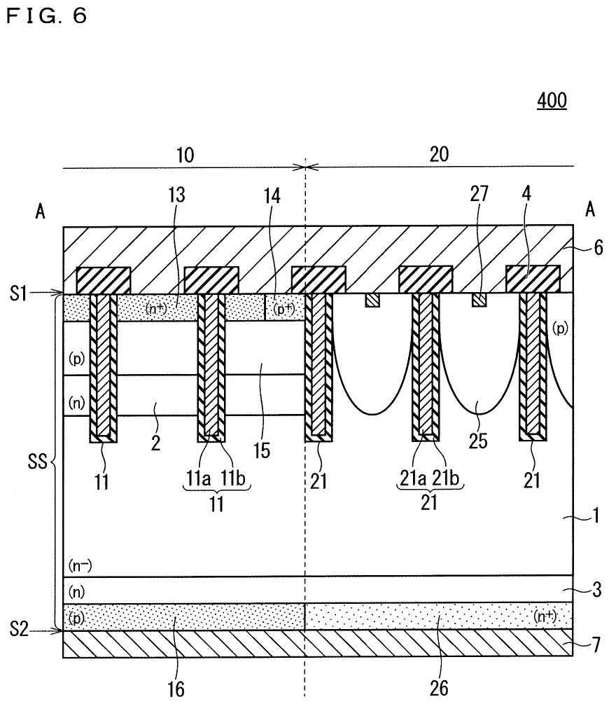

A configuration of an RC-IGBT 400 as a semiconductor device according to a fourth preferred embodiment of the present disclosure will be described with reference to FIG. 6. FIG. 6 is a sectional view illustrating a configuration of the RC-IGBT 400. The plan view is similar to the RC-IGBT 100 illustrated in FIG. 1, and FIG. 6 is a sectional view corresponding to a sectional view taken along line A-A of FIG. 2 as seen in the direction of the arrow.

In FIG. 6, the same components as those of the RC-IGBT 100 of the first preferred embodiment described with reference to FIG. 2 are denoted by the same reference numerals, and redundant description is omitted.

As illustrated in FIG. 6, in the RC-IGBT 400, the anode layer 25 of the diode region 20 is formed below the contact region 27 such that the depth of the anode layer 25 is the deepest, and has a depth distribution in which the depth of the anode layer 25 becomes sharply shallower as the distance from the contact region 27 increases in the horizontal direction, that is, in the direction parallel to the first main surface S1. By adopting such a configuration, the anode layer 25 can be made partially shallow, the electron discharge efficiency from the shallow part can be increased, and the recovery loss can be reduced.

That is, since the anode layer 25 is p-type, a large number of holes become carriers, and thus there is a function of preventing the flow of electrons from the n-type impurity layer in which a large number of electrons become carriers. By making the anode layer 25 partially shallow, the distance by which electrons flow through the anode layer 25 which is a p-type semiconductor layer is shortened, and the electron discharge efficiency can be enhanced.

In order to form the anode layer 25 as illustrated in FIG. 6, the IGBT region 10 of the semiconductor substrate SS is completely covered, and the diode region 20 is formed with a resist material, a silicon oxide film, or the like as an ion implantation mask in which a part forming the anode layer 25 is an opening portion. In this case, by setting the pitch of the opening portions to be shorter than the diffusion distance of the p-type impurity in the horizontal direction, the anode layer 25 is prevented from being disconnected.

### <Fifth Preferred Embodiment>

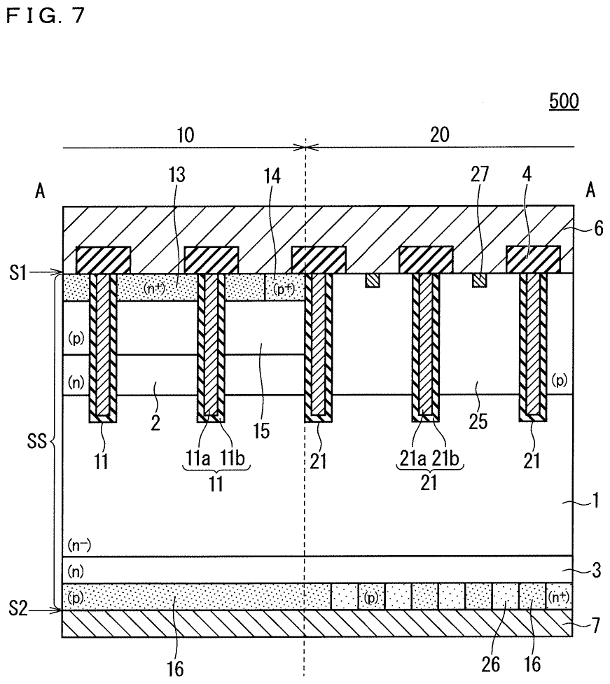

A configuration of an RC-IGBT 500 as a semiconductor device according to a fifth preferred embodiment of the present disclosure will be described with reference to FIG. 7. FIG. 7 is a sectional view illustrating a configuration of the RC-IGBT 500. The plan view is similar to the RC-IGBT 100 illustrated in FIG. 1, and FIG. 7 is a sectional view corresponding to a sectional view taken along line A-A of FIG. 2 as seen in the direction of the arrow.

In FIG. 7, the same components as those of the RC-IGBT 100 of the first preferred embodiment described with reference to FIG. 2 are denoted by the same reference numerals, and redundant description is omitted.

As illustrated in FIG. 7, in the RC-IGBT 500, the cathode layer 26 and the collector layer 16 are alternately formed between the drift layer 1 and the second main surface S2 on the second main surface S2 side of the diode region 20.

The hole discharge efficiency is improved by providing the contact region 27, the electron implantation efficiency is lowered by alternately forming the cathode layer 26 and the collector layer 16, and the recovery loss can be reduced.

### <Sixth Preferred Embodiment>

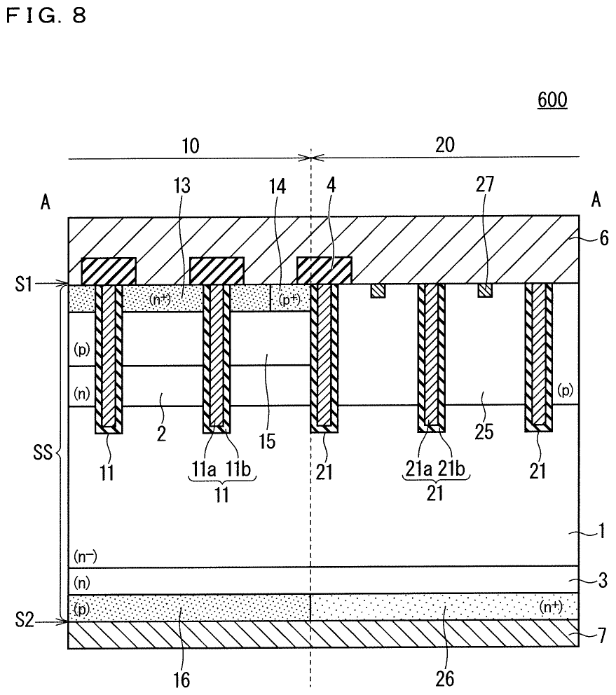

A configuration of an RC-IGBT 600 as a semiconductor device according to a sixth preferred embodiment of the present disclosure will be described with reference to FIG. 8. FIG. 8 is a sectional view illustrating a configuration of the RC-IGBT 600. The plan view is similar to the RC-IGBT 100 illustrated in FIG. 1, and FIG. 8 is a sectional view corresponding to a sectional view taken along line A-A of FIG. 2 as seen in the direction of the arrow.

In FIG. 8, the same components as those of the RC-IGBT 100 of the first preferred embodiment described with reference to FIG. 2 are denoted by the same reference numerals, and redundant description is omitted.

As illustrated in FIG. 8, in the RC-IGBT 600, the interlayer insulating film 4 is provided on the diode trench gate 21 (first diode trench gate) at the boundary part between the IGBT region 10 and the diode region 20, but the interlayer insulating film 4 is not provided on the other diode trench gate 21 (second diode trench gate).

By adopting such a configuration, the contact area between the anode layer 25 and the emitter electrode 6 can be increased, and the hole discharge efficiency can be enhanced.

Since the emitter potential is applied to the diode trench electrode 21a of the diode trench gate 21 even when covered with the interlayer insulating film 4, there is no problem even when the interlayer insulating film 4 is not provided as in the RC-IGBT 600 and the emitter electrode 6 is in contact with the diode trench electrode 21a. By setting the diode trench electrode 21a to the emitter potential, the chip capacitance can be reduced.

### <Seventh Preferred Embodiment>

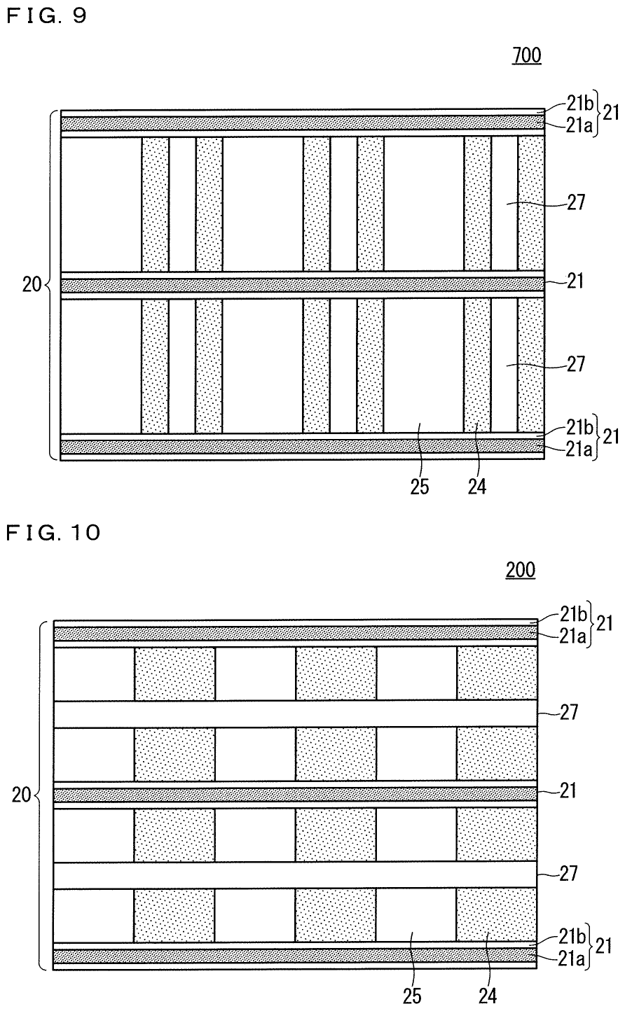

A configuration of an RC-IGBT 700 as a semiconductor device according to a seventh preferred embodiment of the present disclosure will be described with reference to FIG. 9. FIG. 9 is a plan view illustrating a configuration of the RC-IGBT 700, and is an enlarged plan view of only the diode region 20.

As illustrated in FIG. 9, in the RC-IGBT 700, a plurality of diode contact layers 24 are provided at intervals between the adjacent diode trench gates 21, and the contact regions 27 are formed in a stripe shape at the center of each diode contact layer 24 to be perpendicular to the diode trench gate 21.

Even in a case of adopting such a configuration, as described in the second preferred embodiment with reference to FIG. 4, since the bottom portion of the contact region 27 is in contact with the diode contact layer 24, the hole discharge efficiency can be enhanced, but the area in contact with the diode contact layer 24 is wider than the contact region 27 of the second preferred embodiment.

For comparison, FIG. 10 shows an enlarged view of the diode region 20 of the RC-IGBT 200 illustrated in FIG. 3 of the second preferred embodiment. In the RC-IGBT 700, since the diode contact layer 24 is provided between the adjacent diode trench gates 21 and the contact region 27 is vertically provided at the center thereof, the area in contact with the diode contact layer 24 is increased, and the hole discharge efficiency can be further enhanced.

In addition, since the contact region 27 is formed by removing a part of the anode layer 25 including the diode contact layer 24, the contact region 27 is in contact with the anode layer 25 not only on the bottom surface but also on the side surface. Therefore, even when the width of the contact region 27, that is, the contact width is minimized to maintain the aspect ratio to the extent that the embeddability, does not deteriorate, the contact area between the anode layer 25 and the emitter electrode 6 can be increased, and the RRSOA can be improved.

### <Eighth Preferred Embodiment>

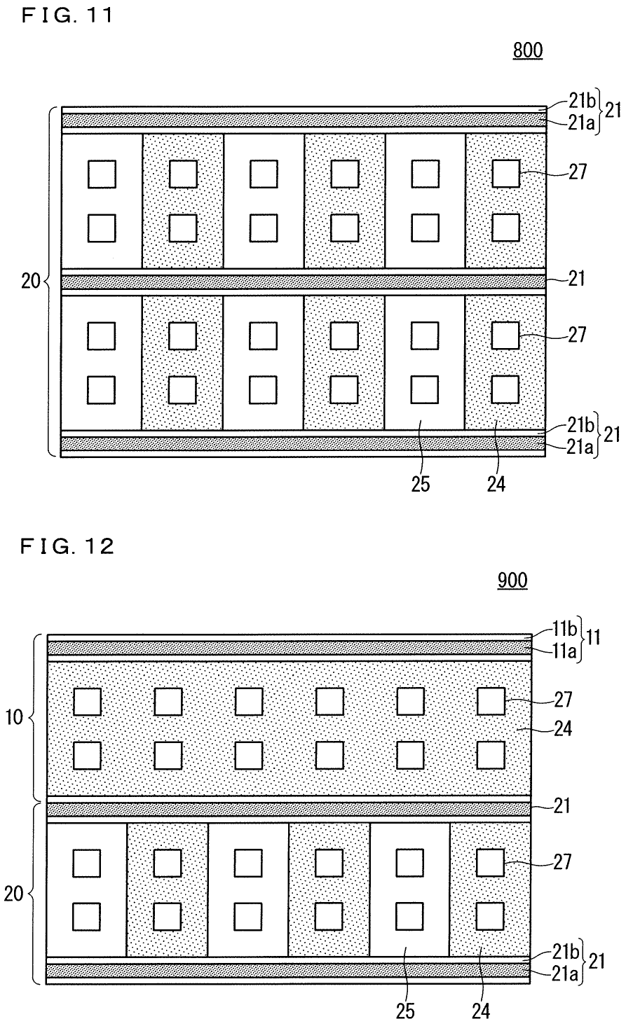

A configuration of an RC-IGBT 800 as a semiconductor device according to an eighth preferred embodiment of the present disclosure will be described with reference to FIG. 11. FIG. 11 is a plan view illustrating a configuration of the RC-IGBT 800, and is an enlarged plan view of only the diode region 20.

As illustrated in FIG. 11, in the RC-IGBT 800, the plurality of diode contact layers 24 are provided at intervals between the adjacent diode trench gates 21, and the plurality of contact regions 27 having a quadrangular shape in plan view are provided in each anode layer 25 between the diode contact layer 24 and the diode contact layer 24. The contact region 27 is not limited to a quadrangular shape, and may be formed in a dot shape or a circle shape as long as the shape is discontinuous.

By evenly disposing the contact region 27 as a discontinuous shape between the adjacent diode trench gates 21, the hole discharge path is equalized, and the RRSOA can be improved.

### <Ninth Preferred Embodiment>

A configuration of an RC-IGBT 900 as a semiconductor device according to a ninth preferred embodiment of the present disclosure will be described with reference to FIG. 12. FIG. 12 is a plan view illustrating a configuration of the RC-IGBT 900, and is an enlarged plan view of only a boundary part between the IGBT region 10 and the diode region 20.

As illustrated in FIG. 12, in the RC-IGBT 900, the IGBT contact layer 14 is not formed in a region sandwiched between the active trench gate 11 and the diode trench gate 21 in the IGBT region 10, and the diode contact layer 24 is entirely formed. On the other hand, the plurality of diode contact layers 24 are provided at intervals between the adjacent diode trench gates 21 of the diode region 20.

The plurality of contact regions 27 having a quadrangular shape in plan view are provided in the diode contact layer 24 of the IGBT region 10 and each anode layer 25 between the diode contact layer 24 and the diode contact layer 24 of the diode region 20.

In the RC-IGBT 900, since the diode contact layer 24 is continuously formed in the region sandwiched between the active trench gate 11 and the diode trench gate 21 of the IGBT region 10 at the boundary part between the IGBT region 10 and the diode region 20, the hole discharge efficiency at the boundary part between the IGBT region 10 and the diode region 20 can be increased.

Although FIG. 12 illustrates the configuration in which the active trench gate 11 is provided at the boundary part between the IGBT region 10 and the diode region 20, when a dummy trench gate is provided instead of the active trench gate 11, the diode contact layer 24 may be continuously formed in a region sandwiched between the dummy trench gate and the diode trench gate 21.

The dummy trench gate is configured by providing a dummy trench electrode in a trench formed in the semiconductor substrate SS via a dummy trench insulating film, and the dummy trench electrode is electrically connected to the emitter electrode 6 and does not function as a gate electrode.

### <Tenth Preferred Embodiment>

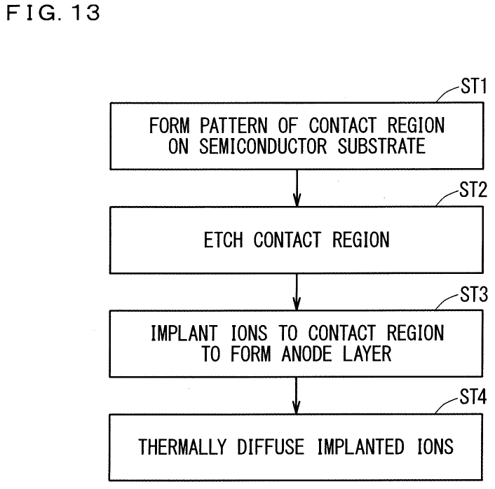

A method of manufacturing the semiconductor device according to a tenth preferred embodiment of the present disclosure will be described with reference to FIG. 13. FIG. 13 is, for example, a flowchart for explaining a method of forming the contact region 27 and the anode layer 25 of the diode region 20 of the semiconductor device of the first preferred embodiment illustrated in FIG. 1.

Step ST1 illustrated in FIG. 13 is a step performed on the semiconductor substrate SS at a stage where the carrier accumulation layer 2 is formed in the IGBT region 10 in the drift layer 1 of the semiconductor substrate SS, and is a step of forming an etching mask for forming a pattern of the contact region 27. The etching mask is provided with an opening portion corresponding to the pattern of the contact region 27.

Next, in step ST2, the semiconductor substrate SS is etched through the opening portion of the etching mask, and the recess portion corresponding to the contact region 27 is patterned.

Next, in step ST3, ions of p-type impurities, for example, boron ions or aluminum ions are ion implanted through the opening portion of the etching mask using the etching mask as an ion implantation mask.

Next, in step ST4, the implanted ions are thermally diffused to form the anode layer 25.

Thereafter, in the step of forming the emitter electrode 6, the part etched in the form of the contact region 27 is filled with the electrode material of the emitter electrode 6, and accordingly, the emitter electrode 6 and the contact region 27 are simultaneously formed.

According to the method of manufacturing the semiconductor device of the tenth preferred embodiment described above, the contact region 27 and the anode layer 25 can be formed with one mask, and the manufacturing cost can be reduced.

The anode layer 25 having a constant depth as illustrated in FIG. 2 can be formed by disposing the etching mask used in step ST1 such that the pitch of the opening portion of the etching mask is sufficiently shorter than the diffusion distance of the p-type impurity in the horizontal direction. On the other hand, by setting the pitch of the opening portions to be shorter than the diffusion distance of the p-type impurity in the horizontal direction, it is possible to form the partially shallow anode layer 25 as illustrated in FIG. 6.

### Other Application Examples

As the semiconductor substrate SS used in the present disclosure described above, for example, an FZ wafer manufactured by a floating zone (FZ) method, an MCZ wafer manufactured by a magnetic field applied Czochralski (MCZ) method, or an epitaxial wafer manufactured by an epitaxial growth method can be applied, but the semiconductor substrate SS is not limited thereto.

In addition, the concentration of the n-type impurity contained in the semiconductor substrate SS is appropriately selected according to the withstand voltage class of the semiconductor device to be manufactured. For example, in a semiconductor device having a withstand voltage of 1200 V, the concentration of the n-type impurity is adjusted such that the specific resistance of then type drift layer 1 constituting the semiconductor substrate SS becomes approximately 40 to 120 Ω·cm.

Note that, in the present disclosure, each preferred embodiment can be freely combined, and each preferred embodiment can be appropriately modified or omitted within the scope of the disclosure.

The present disclosure described above will be collectively described as appendices.

### Appendix 1

A semiconductor device in which a transistor and a diode are formed on a common semiconductor substrate, wherein,

the semiconductor substrate includes
a transistor region in which the transistor is formed, and
a diode region in which the diode is formed,

the diode region includes
a first conductivity type first semiconductor layer provided on a second main surface side of the semiconductor substrate,
a first conductivity type second semiconductor layer provided on the first semiconductor layer,
a second conductivity type third semiconductor layer provided closer to a first main surface side of the semiconductor substrate than the second semiconductor layer,
a first main electrode that applies a first potential to the diode,
a second main electrode that applies a second potential to the diode,
a plurality of diode trench gates provided to reach the second semiconductor layer from the first main surface of the semiconductor substrate, and
a contact region provided in an upper layer portion of the third semiconductor layer, and

the contact region is composed of a conductor material embedded in a recess portion provided in the third semiconductor layer.

### Appendix 2

The semiconductor device according to Appendix 1, wherein

the diode region further includes a second conductivity type fourth semiconductor layer selectively provided in an upper layer portion of the third semiconductor layer, and

the fourth semiconductor layer has
an impurity concentration of the second conductivity type, which is higher than that of the third semiconductor layer, and
a depth of the contact region is shallower than that of the fourth semiconductor layer.

### Appendix 3

The semiconductor device according to Appendix 2, wherein the fourth semiconductor layer is formed below the contact region such that the depth is partially deep.

### Appendix 4

The semiconductor device according to any one of Appendices 1 to 3, wherein the third semiconductor layer has a depth distribution such that a depth becomes deepest below the contact region.

### Appendix 5

The semiconductor device according to any one of Appendices 1 to 4, wherein the first semiconductor layer is provided alternately with a second conductivity type fifth semiconductor layer in an array direction of the plurality of diode trench gates.

### Appendix 6

The semiconductor device according to any one of Appendices 1 to 5, wherein

the plurality of diode trench gates include
a first diode trench gate provided at a boundary between the transistor region and the diode region, and
a second diode trench gate other than the first diode trench gate,

the first diode trench gate is covered with an interlayer insulating film provided between the first diode trench gate and the first main electrode, and

the second diode trench gate is covered with the first main electrode.

### Appendix 7

The semiconductor device according to any one of Appendices 1 to 6, wherein the contact region is provided between adjacent diode trench gates in a stripe shape in parallel with the diode trench gates.

### Appendix 8

The semiconductor device according to any one of Appendices 1 to 6, wherein the contact region is provided between adjacent diode trench gates in a stripe shape perpendicular to the diode trench gates.

### Appendix 9

The semiconductor device according to any one of Appendices 1 to 6, wherein a plurality of the contact regions are provided evenly in a discontinuous shape between adjacent diode trench gates.

### Appendix 10

The semiconductor device according to Appendix 2, wherein

the fourth semiconductor layer is provided at a boundary between the transistor region and the diode region, and

the fourth semiconductor layer of the transistor region is continuously provided along a diode trench gate provided at the boundary.

### Appendix 11

A method of manufacturing the semiconductor device according to Appendix 1, the method comprising:

a step of forming an etching mask having an opening portion for forming a pattern of the contact region on the semiconductor substrate;

a step of etching the semiconductor substrate through the opening portion of the etching mask to pattern a recess portion corresponding to the contact region;

a step of ion implanting ions of impurities of a second conductivity type through the opening portion using the etching mask as an ion implantation mask; and

a step of thermally diffusing the implanted ions to form the third semiconductor layer.

What is claimed is:

1. A semiconductor device in which a transistor and a diode are formed on a common semiconductor substrate, wherein
the semiconductor substrate includes
a transistor region in which the transistor is formed, and
a diode region in which the diode is formed, the diode region includes
a first conductivity type first semiconductor layer provided on a second main surface side of the semiconductor substrate,
a first conductivity type second semiconductor layer provided on the first semiconductor layer,
a second conductivity type third semiconductor layer provided closer to a first main surface side of the semiconductor substrate than the second semiconductor layer,
a first main electrode that applies a first potential to the diode,
a second main electrode that applies a second potential to the diode,
a plurality of diode trench gates provided to reach the second semiconductor layer from the first main surface of the semiconductor substrate, and
a contact region provided in an upper layer portion of the third semiconductor layer, and
the contact region is composed of a conductor material embedded in a recess portion provided in the third semiconductor layer.

2. The semiconductor device according to claim 1, wherein
the diode region further includes a second conductivity type fourth semiconductor layer selectively provided in an upper layer portion of the third semiconductor layer, and
the fourth semiconductor layer has
an impurity concentration of the second conductivity type, which is higher than that of the third semiconductor layer, and
a depth of the contact region is shallower than that of the fourth semiconductor layer.

3. The semiconductor device according to claim 2, wherein the fourth semiconductor layer is formed below the contact region such that the depth is partially deep.

4. The semiconductor device according to claim 1, wherein the third semiconductor layer has a depth distribution such that a depth becomes deepest below the contact region.

5. The semiconductor device according to claim 1, wherein the first semiconductor layer is provided alternately with a second conductivity type fifth semiconductor layer in an array direction of the plurality of diode trench gates.

6. The semiconductor device according to claim 1, wherein
the plurality of diode trench gates include
a first diode trench gate provided at a boundary between the transistor region and the diode region, and
a second diode trench gate other than the first diode trench gate,
the first diode trench gate is covered with an interlayer insulating film provided between the first diode trench gate and the first main electrode, and
the second diode trench gate is covered with the first main electrode.

7. The semiconductor device according to claim 1, wherein the contact region is provided between adjacent diode trench gates in a stripe shape in parallel with the diode trench gates.

8. The semiconductor device according to claim 1, wherein the contact region is provided between adjacent diode trench gates in a stripe shape perpendicular to the diode trench gates.

9. The semiconductor device according to claim 1, wherein a plurality of the contact regions are provided evenly in a discontinuous shape between adjacent diode trench gates.

10. The semiconductor device according to claim 2, wherein
the fourth semiconductor layer is provided at a boundary between the transistor region and the diode region, and
the fourth semiconductor layer of the transistor region is continuously provided along a diode trench gate provided at the boundary.

11. A method of manufacturing the semiconductor device according to claim 1, the method comprising:
a step of forming an etching mask having an opening portion for forming a pattern of the contact region on the semiconductor substrate;
a step of etching the semiconductor substrate through the opening portion of the etching mask to pattern a recess portion corresponding to the contact region;
a step of ion implanting ions of impurities of a second conductivity type through the opening portion using the etching mask as an ion implantation mask; and
a step of thermally diffusing the implanted ions to form the third semiconductor layer.
